(19) United States
(12) Patent Application Publication
(10) Pub. No.: US 2014/0124365 A1
(43) Pub. Date: May 8, 2014

(54) METHOD OF FORMING A CYLINDRICAL SPUTTER TARGET ASSEMBLY

(71) Applicants: Dieter Wurczinger, Bad Vilbel (DE); David Daniel, Devon (GB)

(72) Inventors: Dieter Wurczinger, Bad Vilbel (DE); David Daniel, Devon (GB)

(21) Appl. No.: 14/110,039

(22) PCT Filed: Apr. 29, 2011
(86) PCT No.: PCT/EP11/56846

§ 371 Date: Jan. 16, 2014

(51) Int. Cl. C23C 14/34

(52) U.S. Cl. CPC C23C 14/3414
USPC 204/298.13; 204/298.12; 228/256; 228/221; 228/203

(57) ABSTRACT

In a method of forming a cylindrical sputter target assembly, comprising the steps of: (a) providing a cylindrical backing tube; (b) providing a cylindrical sputter target, the inner diameter of which is larger than the outer diameter of the backing tube; (c) arranging the sputter target about the backing tube; and (d) bonding the sputter target to the backing tube by providing a solder layer between the backing tube and the sputter target; In accordance with the invention step (d) comprises directionally solidifying the solder layer.

The present invention relates to cylindrical sputter target assemblies and to methods of forming the same.

While still in many sputtering processes planar sputtering targets are employed, in recent years increasing efforts were made to provide for rotating cylindrical sputtering targets, because cylindrical sputtering targets provide for a higher efficiency of material use than planar targets.

As in planar targets, also in cylindrical sputtering targets the target material usually is provided on a backing material. Thus, a cylindrical sputtering target typically comprises a carrier or backing tube within which during a sputtering process magnets are provided so as to create the magnetic field for the sputtering process, and through which optionally cooling fluids can be passed during the sputtering process. The sputtering material is provided as a hollow cylindrical layer on the outer side of the backing tube. When forming the sputtering target assembly, the sputter target material either can be deposited directly on the outer side of the backing tube, or the sputter target material first can be formed as a cylindrical tube, or as a plurality of tube segments or sleeves, which then is/are attached to the backing tube. Attachment of the sputter target to the backing tube can be effected by means of a spring or clamp arrangement, by epoxy bonding or, as it is described in U.S. Pat. No. 5,354,446, by providing a solder layer between the backing tube and the sputter target.

While manufacturing the sputter target and the backing tube as individual components has certain advantages over methods in which the sputter target is formed directly on the backing tube, the bonding of the sputter to the backing tube often has been found to not be satisfactory. Considering that sputtering targets during their use in a material deposition process are exposed to severe process conditions, such as high temperatures, high vacuum, large magnetic fields and the like, homogeneity of the bonding between the sputter target and the backing tube is an important factor of product quality, particularly for cylindrical sputtering targets. That is, whereas in planar sputtering targets differences in thermal expansion of the sputter target and the backing plate may result in a shifting of the sputter target with respect to the backing plate, in a cylindrical sputter target assembly there is no room for the cylindrical sputter target and the cylindrical backing plate to move relative to each other in the radial direction, so that differences in thermal expansion of the sputter target and the backing tube always will result in much higher stresses within the components as compared to planar targets. Therefore, if in a cylindrical sputter target the bonding between the sputter target and the backing tube is inhomogeneous, the local stresses created within the sputter target assembly can result in cracks within the sputter target material and in a local spalling of sputter target material from the backing tube. Furthermore, apart from having to reliably hold the target in place, the bond has to provide for good, uniform thermal conduction between the backing tube and the target material. This is important because when the outside of the rotary target is heated during sputter deposition, the heat must be efficiently transferred to the backing tube which is generally water-cooled. Cooling the backing tube reduces the overall temperature of the target and allows a higher sputtering power to be achieved before thermal effects start to limit the performance.

In view of the above, it is an object of the present invention to provide for a method of forming a cylindrical sputter target assembly, by which rotary sputter targets of higher quality and particularly with a uniform and homogenous bonding between the sputter target and the backing plate can be produced.

In a method of forming a cylindrical sputter target assembly comprising the steps of:

(a) providing a cylindrical backing tube;
(b) providing a cylindrical sputter target, the inner diameter of which is larger than the outer diameter of the backing tube;
(c) arranging the sputter target about the backing tube; and
(d) bonding the sputter target to the backing tube by providing a solder layer between the backing tube and the sputter target;

in accordance with the present invention the above object is solved in that in the course of bonding the sputter target to the backing tube the solder layer is directionally solidified.

Upon intensive studies it was found that the uniformity of the bonding can be substantially improved, when the solder layer which is used for bonding the sputter target to the backing tube is directionally solidified. To achieve directional solidification, measures are to be taken to intentionally introduce a temperature gradient during solidifying the solder layer, so that the solder layer does not arbitrarily or omni-directionally solidify, but rather solidification of the solder layer propagates in only one direction throughout the work piece.

Preferred embodiments of the present invention are defined in the dependent claims.

In particular, during solidification of the solder layer, preferably a temperature gradient is established along the longitudinal axis of the sputter target assembly so as to provide for uniformity particularly in the radial direction, which in cylindrical sputter targets is the most critical direction in terms of stresses that during use might be induced within the material.

While directional solidification of the solder layer can be implemented by providing molten solder in between the sputter target and the backing tube, which solder then is directionally solidified varying the temperature of the sputter target assembly in a directional, propagating manner, in preferred embodiments directional solidification is effected by establishing a cooling front during solidification of the solder layer, which cooling front is gradually moved along the longitudinal axis of the sputter target assembly.

Directional solidification of the layer of molten solder that is provided between the sputter target and the backing tube thus can be effected by inducing a temperature gradient in the solder layer, such as by supplying or withdrawing heat in a directional, propagating manner.

In embodiments in which the sputter target assembly during bonding is heated, directional solidification of the molten solder layer can be effected by gradually turning off the heating along the length of the sputter target assembly, so that the molten solder layer gradually is cooled to ambient temperature.

Instead of employing ambient cooling, directional solidification of the molten solder layer can be caused by forced cooling, i.e. by providing refrigeration to the sputter target assembly, wherein a cooling front is established during solidification of the solder layer, which cooling front is gradually moved along the longitudinal axis of the sputter target assembly.

This can be implemented by employing a heat exchange media or a heat exchange means such that a temperature gradient is established along the interior of the backing tube and/or along the exterior of the sputter target.

Thus, during solidification of the solder layer the interior of the backing tube can be gradually filled with a cooling media, such as cooling water. Alternatively or additionally a cooling media can be employed to gradually cool the exterior of the sputter target, such as by arranging the sputter target assembly within a receptacle which is gradually filled with a cooling media, such as cooling water.

When establishing a cooling front during solidification of the solder layer, care has to be taken in selecting the cooling rate. While a higher cooling rate can be used if the materials of the backing tube and of the sputtering target have a similar coefficient of thermal expansion, the cooling rate should be limited in the production of sputter target assemblies wherein the materials of the backing tube and of the sputtering target have different coefficients of thermal expansion. If in the latter case a too high cooling rate is employed, the different thermal expansion of the materials during cooling creates the risk of damages, such as cracks, in the target material.

In dependency of the materials and the dimensioning of the sputter target assembly, the temperatures employed and the characteristics of the cooling media used, the directional solidification process, during which solidification of the solder layer propagates in the longitudinal direction of the sputter target assembly, can take up to several hours.

In addition or alternatively to employing a cooling media, during solidification of the solder layer a heat exchange means can be located within the interior of the backing tube and/or about the exterior of the sputter target, which heat exchange means is operated such that the region or volume within which a heat exchange is effected gradually is moved or increased along the longitudinal axis of the sputter target assembly.

Directional cooling of the molten solder layer which has been introduced between the sputter target and the backing tube can be implemented by moving a cooling ring, such as a water-cooled or air-cooled cooling ring, axially along the sputter target assembly.

In a preferred embodiment of the method of the invention, during solidification of the solder layer, a heat exchange means is located about the exterior of the sputter target, which heat exchange means is operated so that the region within which a heat exchange is effected is gradually increased along the longitudinal axis of the sputter target assembly. Such heat exchange means can be adapted for directional ambient cooling, such as by employing a heater which extends along the length of the sputter target assembly and by which the sputter target assembly is heated to a temperature which facilitates introduction of molten solder into a gap that is formed between the backing plate and the sputter target, wherein upon having filled the gap with molten solder the heater is gradually turned off along the longitudinal axis of the sputter target assembly.

Alternatively, the heat exchange means can be adapted for directional forced cooling, such as by employing a cooler which extends along the length of the sputter target assembly and which during solidification of the solder layer is gradually turned on along the longitudinal axis of the sputter target assembly.

While the solder layer, at least in part, can be pre-formed on the outer side of the backing tube or the inner side of the sputter target, in preferred embodiments of the method a gap is formed between the backing plate and the sputter target when arranging the sputter target about the backing tube, which gap then is filled with molten solder. In most applications such gap and hence the solder layer has a thickness in the range of from 0.7 to 1.5 mm, such as about 1.0 mm, or in the range of from 0.2 to 1.2 mm, such as about 0.5 mm.

When forming the sputter target assembly, the sputter target sleeve(s) and the backing tube preferably are oriented such that their longitudinal axes are concentric and substantially vertical, wherein the molten solder is filled into the gap formed between the sputter target and the backing tube from the bottom of the gap. Orienting the sputter target and the backing tube to be vertical is of particular advantage, when producing lengthy sputter targets, such as sputter targets having a diameter of for example 10 to 20 cm and length of 1 to 5 m, wherein the target cylinder typically has a thickness of 10 to 20 mm, because when orienting lengthy sputter targets in different orientations, such as for example to be horizontal, the sputter target and/or the backing tube may sag, which results in a non-uniform positioning of the sputter target with respect to the backing tube and hence in a solder layer of varying thickness. When orienting the sputter target and the backing tube vertically, filling the solder from the bottom into the gap is preferred, because this facilitates a uniform and gas-free filling of the gap with solder.

In particular, filling the solder into the gap from the bottom avoids the generation of turbulences within the liquid solder material which else could lead to the intake of gas into the liquid solder material. Furthermore, since any gas present in the liquid solder will tend to move upwards within the solder, filling the solder into the gap from the bottom does not impede the egression of any such gas from the solder.

Displacement of air or any other gas present within the gap by molten solder that is filled into the gap can be further assisted by applying a vacuum to the gap.

In order to facilitate the introduction of molten solder into the gap that is formed between the backing plate and the sputter target, the entire sputter target assembly can be heated, preferably to a temperature above the melting point of the solder and preferably using electronically controlled heating elements. In embodiments in which the molten solder is filled into the gap between the backing plate and the sputter target by gravity filling, i.e. by providing a reservoir for molten solder which is located at a level that is above the upper end of the sputter target assembly, also the reservoir as such as well as any lines via which molten solder is passed from the reservoir to the sputter target assembly can be heated, preferably to a temperature above the melting point of the solder.

It has been found that the quality of the bonding can be further improved when, prior to arranging the sputter target about the backing tube, the exterior surface of the backing tube is burnished. The burnishing can be effected by applying a thin layer of molten solder onto the exterior surface of the backing tube and brushing such solder layer into the surface of the backing tube, for example, by using a scratch brush.

Furthermore, it has been found to be advantageous if the exterior surface of the backing tube and/or the interior surface of the sputter target is coated with a bonding layer system. In particularly preferred embodiments the bonding layer system comprises an undercoat which promotes adhesion, for example, an undercoat comprising a layer of titanium, chromium, or an alloy of nickel and chromium, such as nichrome. On top of the undercoat there can be formed an intermediate layer, such as a layer of nickel, a nickel-vanadium alloy or palladium, and a protective top coat, for example, a top coat comprising silver. The bonding layer system can be applied by physical vapor deposition, such as by sputtering, with which particularly uniform coatings can be achieved. It is to be noted that in embodiments in which the exterior surface of the backing tube is burnished prior to bonding the sputter target, burnishing will be effected after coating the backing tube with the bonding layer system.

The solder layer used for bonding the sputter target to the backing tube can comprise primarily indium, i.e. comprises at least 50% indium, and can comprise up to 100% indium. An example of solder layer for use in the method of the present invention comprises a mixture of indium and tin, such as In90:Sn10.

In dependency of the final purpose of the sputtering target a wide variety of materials may be used for manufacturing of the backing tube. Particularly preferred materials for the backing tube are copper, titanium, stainless steel and nickel-plated stainless steel.

With the method of the present invention generally any type of sputter target can be produced and particularly sputter targets comprising elemental, i.e. pure materials, alloys or compounds. Materials for which the present method has been shown to be of particular advantage are ceramic materials, such as indium tin oxide (sometimes abbreviated as ITO), and mixtures of aluminum oxide and zinc oxide, such as ZnO:Al₂O₃ (sometimes abbreviated as AZO), or metals such as copper gallium.

Where the sputter target comprises a ceramic material, and particularly a sintered ceramic material, the sputter target, in addition to ceramic powder, may comprise sintering additives.

It is to be understood that the present method can be applied irrespective of how the backing tube and the sputter target were manufactured. The individual steps of forming or processing the targets after their formation, such as homogenizing the target material, fine-grinding, granulating and pressing the same in a pre-form, be it by isostatic pressing or by uni-axial pressing, pre-machining, sintering, the removal of optional additives, for example, burning-out such additives, as well as the optional final machining, such as cutting, grinding and polishing will not be described herein in further detail.

A preferred embodiment of the method suggested herein will be described below by reference to the drawings, in which:

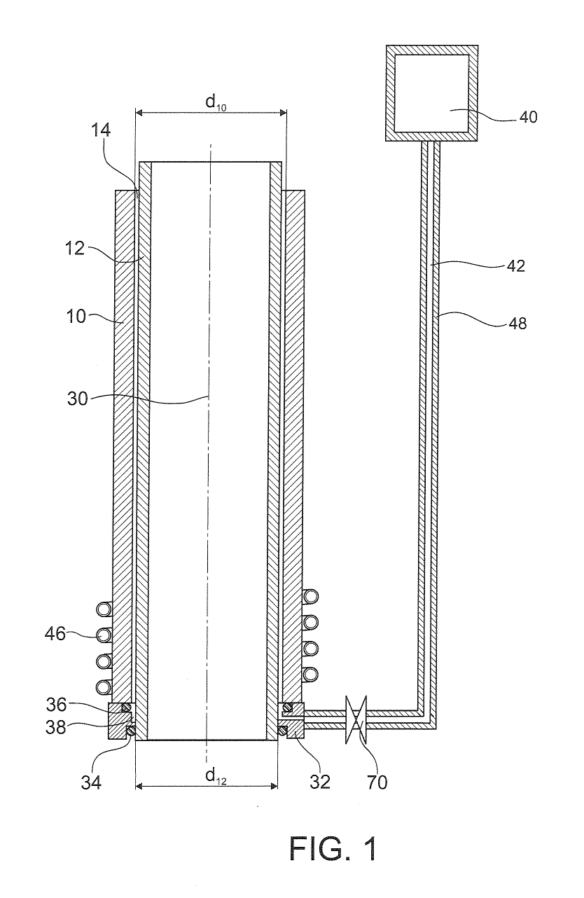

FIG. 1 shows a cross-sectional view of a cylindrical sputter target assembly during manufacturing;

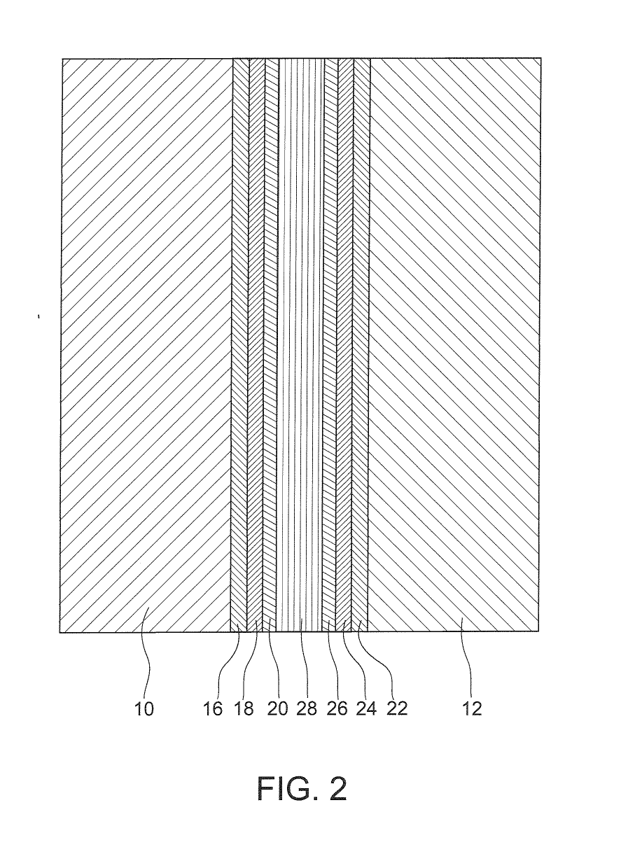

FIG. 2 an enlarged sectional view of the sputter target assembly of FIG. 1 at the end of the manufacturing process;

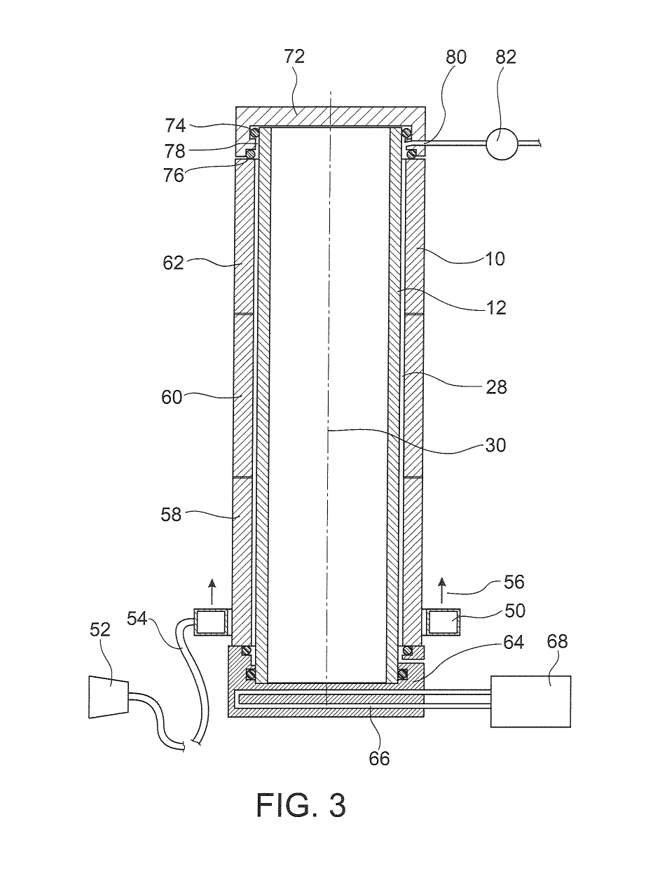

FIG. 3 a schematic view of an apparatus used in the method of the present invention;

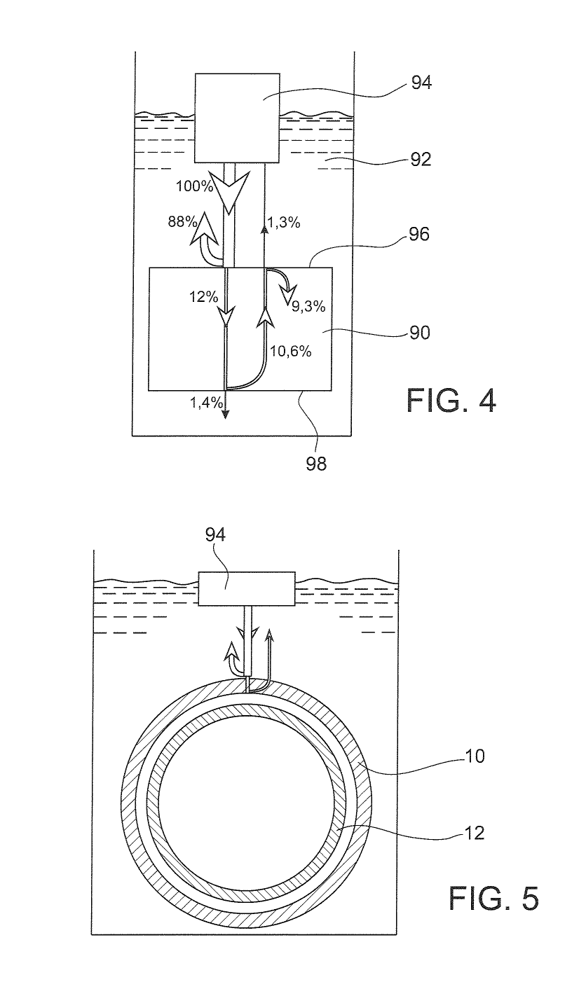

FIG. 4 is a schematic diagram of an ultrasonic testing method when applied to a general test specimen;

FIG. 5 is a schematic diagram of an ultrasonic testing method when applied to a sputter target assembly as produced by the method of the present invention; and

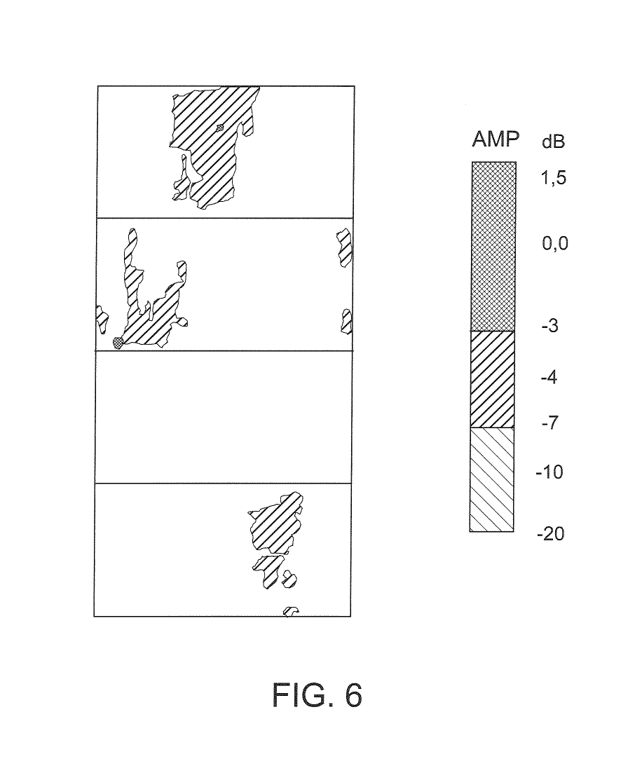

FIGS. 6 to 9 illustrate ultrasonic testing scans of samples of sputter target assemblies of different quality.

The sputter target assembly shown in FIG. 1 comprises a sputter target 10, such as a ceramic sputter target of indium tin oxide. Sputter target 10 is in the shape of a lengthy hollow cylinder having an inner diameter d₁₀, which is arranged concentrically on a cylindrical backing tube 12 having an outer diameter d₁₂. Inner diameter d₁₀ of sputter target 10 is slightly larger than outer diameter d₁₂ of backing tube 12, so that when the sputter target 10 is placed about backing tube 12, a gap 14 is formed, which in the course of the manufacturing process of the sputtering target assembly is filled with solder. The difference in dimension between the outer backing tube d₁₂ and the target material inner diameter d₁₀, which usually is referred to as the bond gap, for many applications is in the region of 1 mm. A typical backing tube can have

FIG. 2 shows an enlarged view of the sputter target assembly of FIG. 1 after gap 14 has been filled with solder. In the embodiment shown in FIG. 2, the inner surface of target 10 and also the outer surface of backing tube 12 were coated with a bonding layer system prior to bonding the sputter target to the backing tube. While different bonding layer systems can be applied to the sputter target and backing tube, FIG. 2 shows an embodiment wherein sputter target 10 and backing tube 12 were coated with the same bonding system.

In particular, sputter target 10 was provided on its inner surface first with an undercoat 16 of titanium so as to promote adhesion of the bonding layer system to the sputter target. Undercoat 16 in turn is coated with an intermediate layer 18 of nickel vanadium, which in turn is coated with a protective layer 20 of silver. Similarly, backing tube 12 is coated with a titanium undercoat 22 on which there is provided a nickel vanadium intermediate layer 24 and a protective silver layer 26. FIG. 2 further shows a solder layer 28, which has been formed in between the coated sputter target and the coated backing tube.

In order to introduce molten solder into gap 14, the cylindrical target and backing tube 12 are arranged such that their axes 30 extend coaxially and are arranged substantially vertical. Then the solder, such as indium or a mixture of indium and tin is heated above its melting point and is introduced into gap 14 from the lower side of gap 14. To this end an annular fixture 32 can be attached about backing tube 12, as it is depicted in FIG. 1. Fixture 32 is sealed against backing tube 12 by means of an O-ring sealing 34 and against sputter target 10 by means of a further O-ring sealing 36. Fixture 32 comprises an annular gap 38, which is in communication with the gap 14 that is formed between sputter target 10 and backing tube 12. Molten solder is fed from a reservoir 40 via feed line 42 into annular recess 38 so as to enter into and raise within gap 14 until gap 14 is completely filled with molten solder. While in the embodiment shown in FIG. 1 molten solder can be passed from reservoir 40 into gap 14 solely by gravity, i.e. by the hydrostatic pressure created by arranging reservoir 40 at a higher level than the upper end of gap 14, if desired a pump can be provided in line 42 so as to pump molten solder into gap 14. In proximity of the point where line 42 adjoins fixture 32 there is provided a valve 70 so as to isolate the solder reservoir 40.

If during filling molten solder into gap 14, the gap shall be evacuated, an additional fixture similar to fixture 32 shown in FIG. 1 can be used at the upper end of the sputter target assembly, such as top cap 72 shown in FIG. 3. Top cap 72 is sealed against backing tube 12 by means of an O-ring sealing 74 and against sputter target 12 by means of a further O-ring sealing 76. Top cap 72 comprises an annular gap 78 which communicates with a fitting 80 to which a vacuum pump 82 is connected. By sealing the entire bond gap and the fixtures at the bottom and top end of the assembly and using a vacuum pump to create a vacuum in the bond gap and in any dead space in the top and bottom fixtures, air bubbles are prevented from forming in the solder bond layer during bonding.

Before and during filling solder into gap 14, the solder should be heated well above its melting point and either then is filled into reservoir 40 from which it is fed into gap 14, or the solder is heated directly within reservoir 40 by appropriate heating means. In order to prevent the molten solder to clod or solidify already within line 42, there is provided an insulation 48 about reservoir 40 and line 42.

Furthermore, a heating coil 46, only part of which is shown in FIG. 1, is arranged about the circumference of sputter target 10 along the length of the sputter target assembly so as to heat the sputter target assembly during filling molten solder into gap 14.

FIG. 3 shows the sputtering target assembly after molten solder has been filled into gap 14 and during solidifying solder layer 28. In order to solidify solder layer 28 heating coil 46 is turned-off or, as shown in FIG. 3 is removed, and a cooling ring 50 is located about the exterior of the sputter target assembly. In the embodiment shown in FIG. 3 the lower end of the sputter target 10 and the backing tube 12 rests on a plinth 64 which on the one hand serves the same purpose as annular fixture 32 shown in FIG. 1, but which additionally allows controlling the temperature at the lower end of the assembly. To this end plinth 64 comprises an internal heating/cooling means 66, such as a conduit through which a heating/cooling media can be flowed by means of a control unit 68. While during filling molten solder into bond gap 14 the plinth 64 may be heated, in order to initiate solidification of the solder, the plinth is cooled at least at the beginning of the solidification process and preferably throughout the entire solidification process.

In the embodiment shown in FIG. 3 cooling ring 50 is an air cooler, which is supplied with air from a pump 52 which is connected to cooling ring 50 via a flexible hose 54. In order to provide for directional solidification of solder layer 28 along the longitudinal axis 30 of the sputter target assembly, cooling ring 50 is slowly moved along the sputter target assembly in a direction as indicated in FIG. 3 by arrows 56 in parallel to longitudinal axis 30. In the embodiment shown in FIG. 3, solder layer 28 thus is directionally solidified from the bottom end to the top end of the sputter target assembly.

It should be noted that while FIG. 1 shows an embodiment wherein sputter target 10 comprises a single unitary cylinder, in the embodiment shown in FIG. 3 the sputter target 10 comprises three segments 58, 60 and 62 which are stacked one above another on backing tube 12. Since for typical applications the sputter target assembly has a length of 0.5 to 5 m, particularly for larger sputter target assemblies forming the sputter target 10 of a plurality of stacked segments facilitates handling and manufacturing of the sputter target assembly.

The individual segments of the sputter target 10 furthermore can be stacked one above another on backing tube 12 so as to be arranged at a slight mutual axial distance. In this manner the can be provided room for expansion of the sputter target material which during use can be exposed to high temperatures. Particular in case that the coefficients of thermal expansion of the backing tube and of the target material substantially differ, providing for gaps between sputter target segments reduces stresses that can be induced in the target material due to a different thermal expansion of the backing tube and of the target material.

From the above it thus it to be seen that the process of forming the sputter target assembly can consist of the following steps:

Place the backing tube vertically on a plinth using an O-Ring and fix the plinth to the backing tube with a clamp.

Arrange the target sleeve(s) concentrically around the backing tube as described above.

Seal the top of the backing tube into the metal header again using “O”-Rings and clamps.

Load the solder reservoir with solid solder ingots of sufficient quantity to fill the entire bond gap.

Seal the top of the solder reservoir by attaching a lid to provide a vacuum seal.

Provide heating elements around the bond assembly such that the rotary target, its assembly jig and the solder jig can all be temperature-controlled. The rotary target bonding assembly is now ready for the bond process to begin.

Close the solder reservoir output valve that isolates the reservoir from the tube assembly.

Heat the complete assembly including the solder reservoir above the melting point of the solder.

Using a vacuum pump, evacuate the solder gap plus the dead space in the top and bottom fixtures such as the bottom plinth and the top-cap assembly. Evacuate also the solder reservoir. Open the isolation valve between the solder reservoir and the rest of the assembly to allow the solder to ingress into the solder gap from the bottom until the solder gap and the plinth and top cap spaces are full with solder.

Close the isolation valve to the solder reservoir.

Begin the directional cooling process by controlled force-cooling of the bottom plinth assembly,

Adjust the temperature profile of the heating oven outside the rotary target so that the temperature reduces gradually from the bottom of the sputter target assembly along the axis of the assembly to the top so as to move the cooling front from one end to the other. As the temperature drops below the melting point of the solder, solidification will occur directionally in a controlled manner, beginning at the bottom and moving to the top.

When the solder in the complete volume of the bond gap and the end fixtures has solidified allow the entire assembly to cool slowly to room temperature.

Once at room temperature, remove the base and the top-cap assemblies from the target.

Submit the target for ultrasonic testing as part of product assessment and performance grading.

In an illustrate example of a method of forming a cylindrical sputter target assembly, a backing tube was employed which was made of stainless steel and which had a diameter of about 133 mm, a length of 3 m and a thickness of 4 mm. The ceramic target cylinder was made of aluminum zinc oxide and had a thickness of 15 mm. The outer surface of the backing tube and also the inner surface of the target tube were coated with a 1^{st} coating of titanium and chromium in a thickness of 50 nm, a 2^{nd} coating of NiV7 in a thickness of 200 nm and a 3^{rd} coating of Ag in a thickness of 150 nm. The bond gap between the backing tube and the target cylinder had a width of about 1 mm.

Prior to filling the bond gap with an Indium solder, the entire assembly was heated to a temperature of nominally 200° C. To provide for directional solidification, first the bottom plinth was cooled to a temperature of 100° C. by flowing water having a temperature of 20° C. through the plinth for about 1 hour. Then the cooling front was slowly moved along the assembly at a rate of about 60 cm/h. When the cooling front had reached the upper end of the target assembly, the assembly was further cooled to a final temperature of about 30° C. by exposing the assembly to room temperature for a minimum of 4 hours.

Non-destructive ultrasonic testing and assessment of the solder layer 28 has shown that by using directional solidification of the solder layer 28 a much more uniform and homogenous bonding can be achieved when compared to prior art methods. Thus, using the method suggested herein higher bonding qualities in terms of the percentage of the total area of the inner surface of the sputter target that is bonded to the outer surface of the backing tube, as determined e.g. by ultrasonic scanning, can be achieved.

Having bonded a rotary target, it is desirable to grade its performance capability in order to define it as a product. Preferably an ultrasonic testing (UT) procedure is used to assess the uniformity and the quality of the bond. These qualities are intrinsically linked to the targets sputtering power handling capability. It defines the performance of the target and hence the product specification.

The ultrasonic testing method used to evaluate the quality of the bond is known as the pulse-echo technique. The method requires a ultrasonic transducer capable of both sending and detecting a ultrasonic signal. Being intrinsically an “in-line” transmit-receive device, the transducer is used to emit signals and then detect those same signals if they reflect back from a defect or from an interface, with the receiver.

In the pulse-echo technique, a signal is sent through a medium, usually water, towards the object to be tested. For illustrative purposes, by reference to FIG. 4 an immersion inspection of a steel block 90 in water 92 is described. In this simplified case, the sound energy leaves the transducer 94, travels through the water 92, encounters the front surface 96 of the steel block 90, encounters the back surface 98 of the steel block and reflects back through the front surface 96 on its way back to the transducer 94. Considering that the energy reflected at a water-stainless steel interface is 0.88 or 88%, at the water steel interface (front surface), only 12% of the energy is transmitted. At the back surface, 88% of the 12% that made it through the front surface, or 10.6% of the intensity of the initial incident wave, is reflected. As the wave exits the part specimen through the front surface, only 12% of such 10.6% or 1.3% of the original energy is transmitted back to the transducer.

In the more complicated case where the surfaces are rough and there may be isolated inhomogeneities in the material, the signal passes through the water until incident upon the object whereupon it is reflected at the surface, attenuated by scattering due to surface roughness or by any defects, or reflected back by these material inhomogeneities. The remaining portion of the signal continues propagating through the object until it is incident on another interface or defect where it will again be reflected and partially attenuated.

The amplitude of the reflected signal and the time gap between the sent and the return signal(s) are a measure of the nature of the interfaces and the distance below the surface, respectively. The amplitude of the reflected signal is a function of the magnitude of the originally-transmitted signal minus the attenuated signal minus the signal which continues to propagate though the object. Ultrasonic attenuation, which is the sum of the absorption and the scattering, is mainly dependent upon the damping capacity and scattering from the material interface(s) which the signal encounters or from any anomalies in the material.

If there are a number of interfaces within the solid, there will be a series of reflected signals which reveal information about the nature of the materials at each interface. Therefore analysis of these signals, especially if used in scanning mode, can be used to expose localised defects at the interfaces.

If the ultrasonic transducer and the object, in this case the sputter target assembly, are placed in a water bath, the ultrasonic signal will first be transmitted through the water until it meets the outer surface of the target perpendicular to the surface, as it is illustrated in FIG. 5. Here it will be partially absorbed and partially reflected. This reflected, attenuated signal can be detected by the transducer. The reflected signal should be sharp with relatively little attenuation as the interface between the water and the target is a simple liquid/solid interface.

The next interface which the transmitted ultrasonic signal encounters will be the target/outer bond layer interface. On reaching this interface, a portion of the signal will be reflected whilst the rest will be attenuated or continue to transmit through the bond medium. The characteristics of the target/solder bond interface are crucial to how much the signal is reflected, attenuated or further transmitted. A well-bonded region should produce a clear, well-defined reflected signal of spectral width similar to the input signal but if the interface is ill-defined, as in the case of an area of a bond which has detached from the target material, then the signal will be severely attenuated by absorption in the air-gap and scattered by roughness of the interface. The attenuation can thus be used as a qualitative measurement of the bond quality.

The sent signal usually consists of around 50-1000 pulses per second and these are directed at the sample (in this case perpendicular to the wall of the bonded target) to be tested. If the ultrasonic transducer can be moved in the direction parallel to the axis of the tubular target assembly, a linear scan of part of the tube target can be obtained. Furthermore, if the target is turned or indexed by rotating for example by 1 degree at a time, a 360-linescan of the complete target bond can be achieved.

If the signal attenuation measured by the transducer can be represented by different colours, dependent on the degree of attenuation, then a coloured pictorial representation of the target/bond interface can be created. An example is shown in FIG. 6 which shows an ultrasonic testing scan of a rotary target wherein the target circumference is shown along the x-axis and the target length along the y-axis. While during the actual measurements a color code was employed to visualize the degree of attenuation by which color code an attenuation in a range of −20 dB to 1.5 dB could be displayed in a continuous range of colors which basically covered the full color spectrum, for ease of illustration, in the attached drawings the scale of attenuation is shown to be divided in three subranges including a low attenuation of −20 to −7 dB shown in light grey, a medium attenuation of −7 to −3 dB shown in hatching and a high attenuation of −3 to 1.5 dB shown in dotted black.

In the tests that produced the results illustrated in FIGS. 6 to 9 the UT scans were set up so that the maximum reflected signal coming from the target surface is 20% below full scale on the output screen. At this point, the other peaks from the different interfaces within the target, such as the solder/target interface, are very small by comparison. Then, all the signal spectrum was amplified by +16 dB so as to increase the height of all the peaks to get more sensitivity. The signal reflected from the outer surface is now well off scale, but the other smaller signals are now well visible on the display screen. It should be understood, that the scale of attenuation of the ultrasonic transducer signal referred to herein of course is dependent on the characteristics and adjustments of the scanning system such as the strength of the signal from the ultrasonic source used in the scanner. Therefore, the scale referred to herein should not be considered as an absolute scale.

Using the above set-up, an area was categorized to be near perfect and have a good quality bonding interface, if it exhibited a relatively low attenuation of −20 dB to −7 dB, which in FIGS. 6 to 9 is shown in light grey, which thus indicates a strong ultrasonic signal. Areas exhibiting an attenuation of between −7 dB to −3 dB, shown in cross-hatched lines in FIGS. 6 to 9, were categorized to be good but not quite so perfect. Areas showing an attenuation of −3 dB to +1.5 dB, which indicated a weak reflected and thus strongly attenuated ultrasonic signal were considered to indicate an insufficient bonding, and are shown in FIGS. 6 to 9 in black color with white dots. Such regions with insufficient or failed bonding may lead to localized heating during target operation as the thermal conduction, and hence cooling effectiveness, of the bond in those regions is diminished.

The ultrasonic testing scan thus allows to easily distinguish regions of low absorption (strong reflected signal, i.e. good quality bonding interface) from regions of high absorption (weak reflected signal, i.e. poor bond interface).

In assessing and categorizing the bonding quality of rotary sputter targets by using the ultrasonic testing scans as explained above, the sputter target assemblies preferably are evaluated in a three step assessment procedure, wherein in a first level of assessment the overall target area is evaluated.

1^{st} Level of Assessment
Evaluation of overall target assembly
percentage of total target area

| dotted black | Power Handling |
|---|---|
| <5% | High |
| 5%-10% | Medium |
| >10% | Unacceptable |

As indicated in the above table, in case that less than 5 percent of the overall target area exhibits an attenuation of −3 dB to +1.5 dB (illustrated in FIGS. 6 to 9 in dotted black), the sputter target assembly is categorized as a good quality product suitable for a handling high power during a sputtering process. If the sputter target assembly exhibits a high or medium power handling, in a second level of assessment the bond quality of the individual sleeves is evaluated.

The second level of assessment takes into account that the sputter target assemblies produced by the method suggested herein and which typically have a length of 0.5 to 5 m, preferably are made up of a plurality of individual sleeves which are arranged in a stacked configuration on the backing tube. In the second level of assessment each sleeve is evaluated individually, wherein a similar categorization scheme is applied as in the first level of assessment.

2^{nd} Level of Assessment
Sleeve Evaluation
percentage of individual sleeve area

| Red/Yellow | Power Handling |
|---|---|
| <5% | High |
| 5%-10% | Medium |
| >10% | Unacceptable |

Provided that in the second level of assessment the sputter target
assembly has not been categorized as unacceptable because in any
of the individual sleeves more than 10% of the sleeve area exhibit an
attenuation of −3 dB to +1.5 dB (illustrated in FIGS. 6 to 9 in dotted
black), evaluation of the sputter target assembly carries on to a third
level of assessment, in which it is determined whether there are any
individual spots within a sleeve that could fail early and cause the
complete target to eventually fail. In such third level assessment, the
actual size of individual spots exhibiting an attenuation of −3 dB
to +1.5 dB is measured. 3^{rd} Level of Assessment
Individual Spots

| Red/Yellow | | Power Handling |
|---|---|---|
| 0-4 | cm² | High |
| 4-10 | cm² | Medium |
| >10 | cm² | Unacceptable |

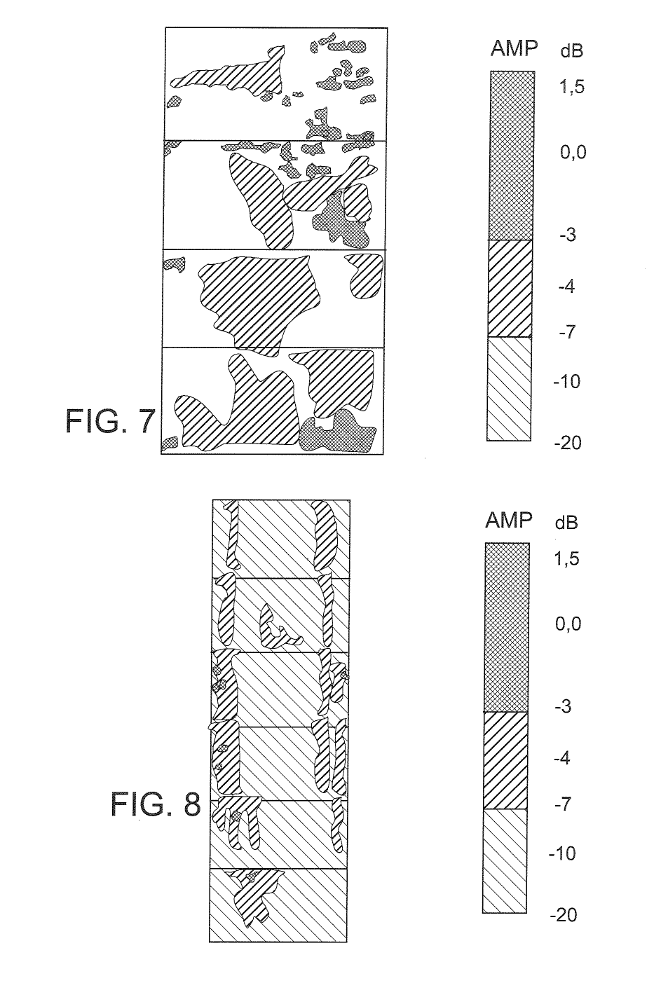

In particular, where the ultrasonic testing scan shows large dotted black regions (>10 cm²) on a two-dimensional ultrasonic testing scan, as it can be seen in the scan shown in FIG. 7 especially in the lower right-hand-side, the performance of the target could be severely compromised and this will limit the power handling capability during sputtering. The target will thus be categorized as a low power product which can be used for sputtering but only at low power densities. In FIG. 8, the ultrasonic testing scan shows some regions of dotted black to be seen on the sonar graphic but they are small islands (<5 mm²) and do not lead to major degradation of the cooling characteristics of the target in those areas. Therefore this target would be categorised as “Good” and could be used for moderate to high power applications.

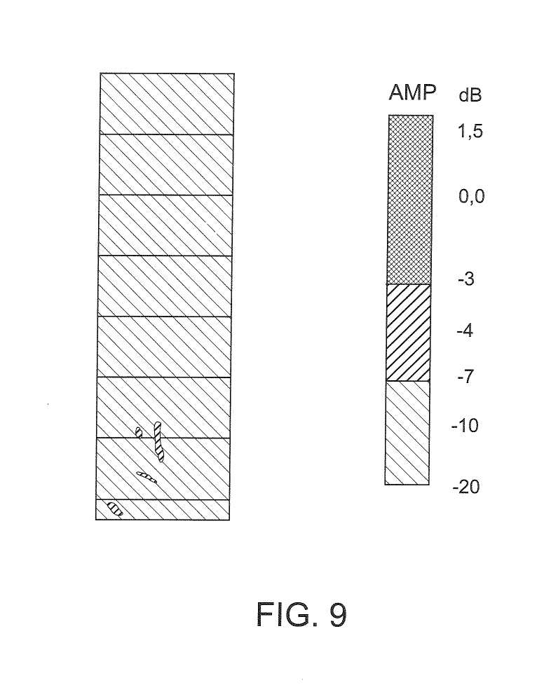

In FIG. 9, the entire ultrasonic testing scan is light grey indicating a good reflected signal at the target/solder interface and hence a very good, uniform bond. This target would be categorised as “Excellent” and would be useable in high sputtering power applications. It represents a premium grade product.

As can be seen from the above, using the ultrasonic scanning technique to evaluate the quality of the target/bond interface, it is possible to use the technique as a tool in conjunction with the target manufacturing process to define the performance of the product.

Using the sputter target manufacturing technique suggested herein, wherein a solder bonding method is employed to attach cylinders or “sleeves” of the target material to a metal backing tube followed by an ultra-sonic test scanning process to evaluate and categorize the product, this combination of process and non-destructive evaluation enables a product to be produced which is categorised for bond integrity and power-handling performance.

### LIST OF REFERENCE SIGNS

10 sputter target
12 cylindrical backing tube
14 gap
16 undercoat of 10
18 intermediate layer of 10
20 protective layer of 10
22 undercoat of 12
24 intermediate layer of 12
26 protective layer of 12
28 solder layer
30 axes of 10 and 12
32 annular fixture
34 O-ring sealing
36 O-ring sealing
38 annular gap
40 reservoir
42 feed line
46 heating coil
48 insulation
50 cooling ring
52 pump
54 flexible hose
56 direction of movement of 50
58 segment
60 segment
62 segment
64 plinth
66 heating/cooling means
68 control unit
70 valve
72 top cap
74 O-ring sealing
76 O-ring sealing
78 annular gap
80 fitting
82 vacuum pump
90 steel block
92 water
94 transducer
96 front surface
98 back surface

1. A method of forming a cylindrical sputter target assembly, comprising the steps of:
(a) providing a cylindrical backing tube;
(b) providing a cylindrical sputter target, the inner diameter of which is larger than the outer diameter of the backing tube;
(c) arranging the sputter target about the backing tube; and
(d) bonding the sputter target to the backing tube by providing a solder layer between the backing tube and the sputter target;
characterized in that step (d) comprises directionally solidifying the solder layer.

2. The method of claim 1, in which during solidification of the solder layer a temperature gradient is established along the longitudinal axis of the sputter target assembly.

3. The method of claim 2, in which during solidification of the solder layer a cooling front is established which is gradually moved along the longitudinal axis of the sputter target assembly.

4. The method of claim 3, in which during solidification of the solder layer the interior of the backing tube is gradually filled with a cooling media.

5. The method of claim 3, in which during solidification of the solder layer a heat exchange means is located within the interior of the backing tube, which heat exchange means is operated so that the region within which a heat exchange is effected gradually moves along the longitudinal axis of the sputter target assembly.

6. The method of claim 3, in which during solidification of the solder layer a heat exchange means is located within the interior of the backing tube, which heat exchange means is operated so that the region within which a heat exchange is effected is gradually increased along the longitudinal axis of the sputter target assembly.

7. The method of any one of claim 3, in which during solidification of the solder layer a heat exchange means is located about the exterior of the sputter target, which heat exchange means is operated so that the region within which a heat exchange is effected gradually moves along the longitudinal axis of the sputter target assembly.

8. The method of claim 7, in which during solidification of the solder layer a cooling ring is moved axially along the sputter target assembly.

9. The method of any one of claim 3, in which during solidification of the solder layer a heat exchange means is located about the exterior of the sputter target, which heat exchange means is operated so that the region within which a heat exchange is effected is gradually increased along the longitudinal axis of the sputter target assembly.

10. The method of claim 6, in which said heat exchange means comprises a plurality of heat exchange sections which are located along the longitudinal axis of the sputter target assembly, and wherein during solidification of the solder layer said heat exchange sections are operated in a sequential manner.

11. The method of claim 1, in which in step (c) a gap is formed between the backing plate and the sputter target, and in which step (d) comprises filling molten solder into said gap.

12. The method of claim 11, in which during step (d) the sputter target and the backing tube are oriented such that their longitudinal axes are substantially vertical, and wherein the molten solder is filled into said gap from the bottom of said gap.

13. The method of claim 11, in which during filling molten solder into said gap a vacuum is applied to said gap.

14. The method of any one of claim 11, in which, during filling molten solder into the gap, the sputter target assembly is heated, preferably to a temperature above the melting point of the solder.

15. The method of claim 1, in which prior to step (c) the exterior surface of the backing tube is burnished.

16. The method of claim 1, in which prior to step (c) the exterior surface of the backing tube and/or the interior surface of said sputter target is coated with a bonding layer system.

17. The method of claim 16, in which said bonding layer system comprises an undercoat promoting adhesion, an intermediate layer and a protective topcoat.

18. The method of claim 17, in which said undercoat comprises a layer of titanium, chromium or an alloy of nickel and chromium, said intermediate layer comprises nickel, a nickel vanadium alloy or palladium, and said topcoat comprises silver.

19. The method of claim 16, in which said bonding layer system is applied by physical vapor deposition.

20. The method of claim 1, in which said solder layer comprises primarily indium, and preferably consists of indium.

21. A cylindrical sputter target assembly having a bond strength as measured by an ultrasonic scanner, comprising:
a cylindrical backing tube having an outer diameter;
a cylindrical sputter target having an inner diameter larger than the outer diameter of the cylindrical backing tube, where the cylindrical backing tube is disposed coaxially within the cylindrical sputter target,
the sputter target and the backing tube being bonded by a solder material, wherein the bond has on average a −3 dB to +1.5 dB attenuation as measured by an ultrasonic scanner.

22. The cylindrical sputter target assembly of claim 21, wherein the cylindrical sputter target includes several individual segments.

23. The cylindrical sputter target assembly of claim 22, wherein for any one particular individual segment bonded to the sputter target there is no individual spot greater than 10 cm² which has an attenuation outside the range of −3 dB to +1.5 dB as measured by the ultrasonic scanner.

24. The cylindrical sputter target assembly of claim 21, wherein the backing tube is made of copper, titanium, stainless steel or nickel plate stainless steel.

25. The cylindrical sputter target assembly of claim 21, wherein the sputter target is a ceramic material.

26. The cylindrical sputter target assembly of claim 21, wherein the ceramic material comprises indium tin oxide, aluminum zinc oxide, copper gallium and mixtures of aluminum oxide.
